(19) United States
(12) Patent Application Publication
(10) Pub. No.: US 2021/0111094 A1
(43) Pub. Date: Apr. 15, 2021

(54) SEMICONDUCTOR PACKAGE AND SEMICONDUCTOR PACKAGE MODULE INCLUDING THE SAME

(71) Applicant: SAMSUNG ELECTRONICS CO., LTD., SUWON-SI (KR)

(72) Inventors: Youngja KIM, Cheonan-si (KR); Yongjin KIM, Incheon (KR)

(21) Appl. No.: 17/019,522

(22) Filed: Sep. 14, 2020

(30) Foreign Application Priority Data
Oct. 11, 2019 (KR) 10-2019-0126290

(51) Int. Cl. H01L 23/367; H01L 23/31; H01L 23/498; H01L 23/00; H01L 25/065; H01L 25/10

(52) U.S. Cl. CPC H01L 23/3675; H01L 2224/73265; H01L 23/49838; H01L 24/16; H01L 24/32; H01L 24/48; H01L 24/73; H01L 25/0657; H01L 25/105; H01L 2225/06506; H01L 2225/0651; H01L 2225/06568; H01L 2225/06586; H01L 2225/06589; H01L 2224/16227; H01L 2224/32225; H01L 2224/48227; H01L 23/3128

(57) ABSTRACT

A semiconductor package includes a circuit substrate including a ground pad. At least one semiconductor chip is disposed on the circuit substrate and is electrically connected to the circuit substrate. An encapsulation layer encapsulates the at least one semiconductor chip. A heat spreader surrounds the encapsulation layer. The heat spreader includes a side heat spreader disposed on a first surface of the circuit substrate and lateral side surfaces of the encapsulation layer. The side heat spreader is connected to the ground pad. A surface heat spreader is disposed on an upper surface of the encapsulation layer.

### CROSS-REFERENCE TO RELATED APPLICATION

This application claims priority under 35 U.S.C. § 119 to Korean Patent Application No. 10-2019-0126290, filed on Oct. 11, 2019 in the Korean Intellectual Property Office, the disclosure of which is incorporated by reference in its entirety herein.

### 1. TECHNICAL FIELD

The present inventive concepts relate to a semiconductor package and a semiconductor package module including the semiconductor package, and more particularly, to a semiconductor package having improved heat dissipation performance and a semiconductor package module including the semiconductor package.

### 2. DISCUSSION OF RELATED ART

In view of recent trends concerning the downscaling of semiconductor chips and semiconductor devices and an increase in the integration density thereof, semiconductor packages need to effectively discharge (or dissipate) heat generated by the semiconductor chips mounted therein to the outside. In addition, a semiconductor package module in which a plurality of semiconductor packages are mounted on a module circuit substrate also needs to externally discharge (or dissipate) heat generated by a plurality of semiconductor chips in the plurality of semiconductor packages to the outside.

### SUMMARY

Exemplary embodiments of the present inventive concepts provide a semiconductor package, which may efficiently emit (or dissipate) heat generated by a semiconductor chip mounted therein to the outside.

Exemplary embodiments of the present inventive concepts also provide a semiconductor package module, which may efficiently emit (or dissipate) heat generated by each of a plurality of semiconductor packages mounted therein to the outside, when the plurality of semiconductor packages are mounted apart from each other on a module circuit substrate in a view from the above.

According to an exemplary embodiment of the present inventive concepts, a semiconductor package includes a circuit substrate including a ground pad. At least one semiconductor chip is disposed on the circuit substrate and is electrically connected to the circuit substrate. An encapsulation layer encapsulates the at least one semiconductor chip. A heat spreader surrounds the encapsulation layer. The heat spreader includes a side heat spreader disposed on a first surface of the circuit substrate and lateral side surfaces of the encapsulation layer. The side heat spreader is connected to the ground pad. A surface heat spreader is disposed on an upper surface of the encapsulation layer.

According to another exemplary embodiment of the present inventive concepts, a semiconductor package includes a circuit substrate comprising a ground pad disposed on a first surface of the circuit substrate. An external connection terminal is disposed on a second surface of the circuit substrate. The external connection terminal is connected to the ground pad through an internal interconnection. At least one semiconductor chip is disposed on the first surface of the circuit substrate and is electrically connected to the circuit substrate. An encapsulation layer encapsulates the at least one semiconductor chip. A heat spreader surrounds the encapsulation layer. The heat spreader comprises a side heat spreader disposed on a top surface of the circuit substrate and lateral side surfaces of the encapsulation layer. The side heat spreader is connected to the ground pad and is configured to dissipate heat by conduction through the circuit substrate. A surface heat spreader is disposed on an upper surface of the encapsulation layer and comprises a pattern structure having a plurality of through grooves that are spaced apart from each other or a plurality of recess grooves that are spaced apart from each other. The surface heat spreader is configured to dissipate heat by convection through the pattern structure.

According to another exemplary embodiment of the present inventive concepts, there is provided a semiconductor package module that includes a module circuit substrate having a module ground pad. A plurality of semiconductor packages is connected to the module ground pad through an external connection terminal disposed on the module circuit substrate. The plurality of semiconductor packages are spaced apart from each other. At least one of the plurality of semiconductor packages comprises a circuit substrate including a ground pad connected to the external connection terminal through an internal interconnection. At least one first semiconductor chip is disposed on the circuit substrate and is electrically connected to the circuit substrate. An encapsulation layer encapsulates the at least one first semiconductor chip. A heat spreader surrounding the encapsulation layer. The heat spreader comprises a side heat spreader disposed on a top surface of the circuit substrate and lateral side surfaces of the encapsulation layer. The side heat spreader is connected to the ground pad of the circuit substrate. A surface heat spreader is disposed on an upper surface of the encapsulation layer.

### BRIEF DESCRIPTION OF THE DRAWINGS

Exemplary embodiments of the present inventive concepts will be more clearly understood from the following detailed description taken in conjunction with the accompanying drawings in which:

FIG. 1A is a cross-sectional view of a semiconductor package according to an exemplary embodiment of the present inventive concepts;

FIG. 1B is a cross-sectional view illustrating the flow of heat generated in a semiconductor chip of the semiconductor package of FIG. 1A according to an exemplary embodiment of the present inventive concepts;

FIG. 2A is a cross-sectional view of a semiconductor package according to an exemplary embodiment of the present inventive concepts;

FIG. 2B is a cross-sectional view illustrating the flow of heat generated in a semiconductor chip of the semiconductor package of FIG. 2A according to an exemplary embodiment of the present inventive concepts;

FIG. 3A is a cross-sectional view of a semiconductor package according to an exemplary embodiment of the present inventive concepts;

FIG. 38 is a cross-sectional view illustrating the flow of heat generated in a semiconductor chip of the semiconductor package of FIG. 3A according to an exemplary embodiment of the present inventive concepts;

FIG. 4A is a cross-sectional view of a semiconductor package according to an exemplary embodiment of the present inventive concepts;

FIG. 4B is a cross-sectional view illustrating the flow of heat generated in a semiconductor chip of the semiconductor package of FIG. 4A according to an exemplary embodiment of the present inventive concepts;

FIG. 5A is a cross-sectional view of a semiconductor package according to an exemplary embodiment of the present inventive concepts;

FIG. 5B is a cross-sectional view illustrating the flow of heat generated in a semiconductor chip of the semiconductor package of FIG. 5A according to an exemplary embodiment of the present inventive concepts;

FIG. 6A is a cross-sectional view of a semiconductor package according to an exemplary embodiment of the present inventive concepts;

FIG. 6B is a cross-sectional view illustrating the flow of heat generated in a semiconductor chip of the semiconductor package of FIG. 6A according to an exemplary embodiment of the present inventive concepts;

FIGS. 7A and 7B are plan views of a semiconductor package module according to exemplary embodiments of the present inventive concepts;

FIG. 8 is a cross-sectional view of a semiconductor package module according to an exemplary embodiment of the present inventive concepts;

FIG. 9 is a cross-sectional view of a semiconductor package module according to an exemplary embodiment of the present inventive concepts;

FIG. 10 is a cross-sectional view of a semiconductor package module according to a comparative example to be compared with the semiconductor package modules of FIGS. 8 and 9;

FIG. 11 is a cross-sectional view of a semiconductor package module system according to an exemplary embodiment of the present inventive concepts; and

FIG. 12 is a cross-sectional view of a semiconductor package module system according to a comparative example to be compared with the semiconductor package module system of FIG. 11.

### DETAILED DESCRIPTION OF EXEMPLARY EMBODIMENTS

Hereinafter, exemplary embodiments of the present inventive concepts will be described in detail with reference to the accompanying drawings. The same reference numerals are used to denote the same elements in the drawings, and repeated descriptions thereof will be omitted.

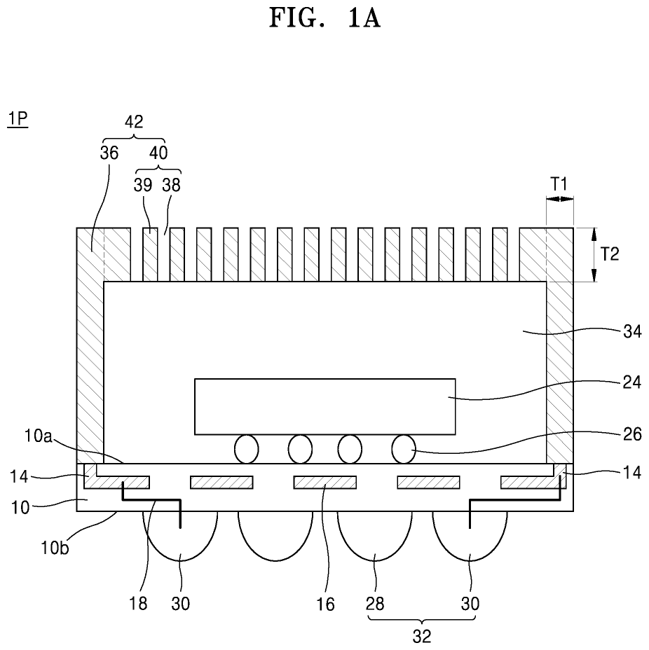

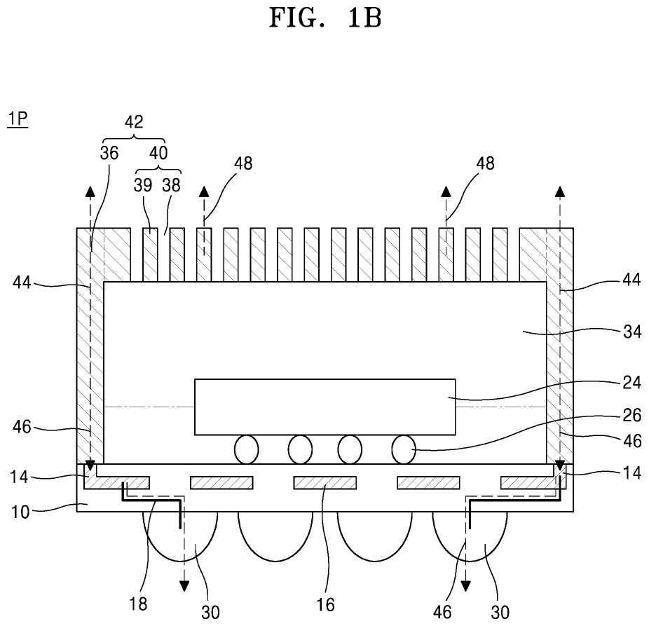

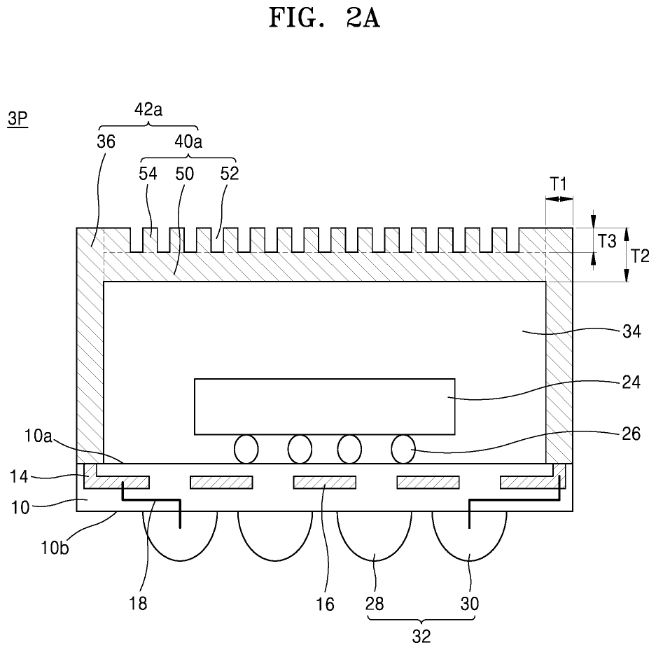

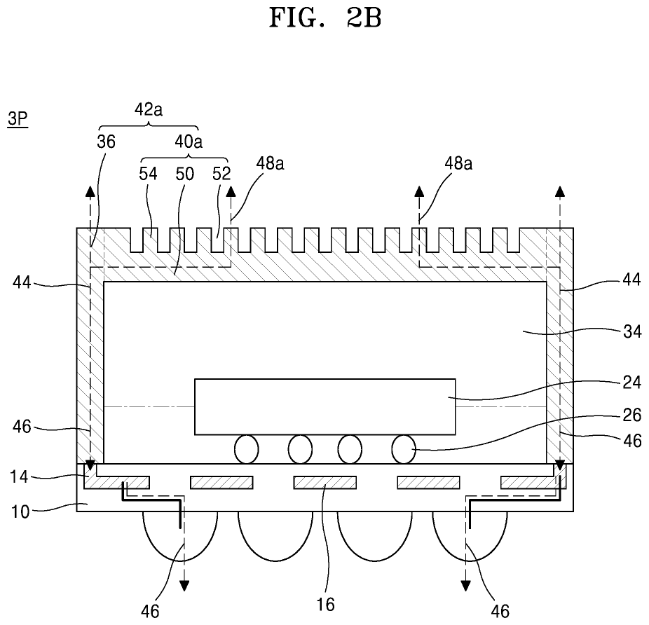

FIG. 1A is a cross-sectional view of a semiconductor package 1P according to an exemplary embodiment of the present inventive concepts, and FIG. 1B is a cross-sectional view illustrating the flow of heat generated in a semiconductor chip 24 of the semiconductor package 1P of FIG. 1A according to an exemplary embodiment of the present inventive concepts.

As shown in the exemplary embodiment of FIG. 1A, the semiconductor package 1P may include the semiconductor chip 24 mounted on a circuit substrate 10. Although the exemplary embodiments shown in FIGS. 1A and 1B include only one semiconductor chip 24 mounted on the circuit substrate 10, a plurality of semiconductor chips may be adhered to or mounted to the circuit substrate 10. In an exemplary embodiment, the plurality of semiconductor chips 24 may be connected to each other by a through-silicon via (TSV). In an exemplary embodiment, the circuit substrate 10 may be a printed circuit board (PCB). The circuit substrate 10 may include a first surface 10a and a second surface 10b, which is opposite to the first surface 10a. For example, as shown in the exemplary embodiment of FIG. 1A, the first surface 10a may be an upper surface of the circuit substrate 10 and the second surface 10b may be a lower surface of the circuit substrate 10.

The circuit substrate 10 may include a ground pad 14, a ground interconnection 16, and an internal interconnection 18. The ground pad 14 may ground the semiconductor chip 24. The ground pad 14 may be connected to the ground interconnection 16. As shown in the exemplary embodiment of FIG. 1A, the ground pad 14 may have an exposed surface at the first surface 10a of the circuit substrate 10. For example, as shown in the exemplary embodiment of FIG. 1A, the ground pad 14 may include a portion below the first surface 10a of the circuit substrate 10 that extends in a direction parallel to an upper surface of the circuit substrate 10. The ground pad 14 may also include a portion that extends in a thickness direction of the circuit substrate 10 which extends to the first surface 10a to expose the ground pad 14. However, exemplary embodiments of the present inventive concepts are not limited thereto and the ground pad 14 may have various different shapes and configurations. A signal pad may be disposed in the circuit substrate 10 and may transmit signals to the semiconductor chip 24 or transmit signals to the outside. A signal interconnection may be disposed in the circuit substrate 10 and connected to the signal pad.

In an exemplary embodiment, the semiconductor chip 24 on which an internal connection terminal 26 is disposed may be mounted on (e.g., disposed on) the first surface 10a of the circuit substrate 10. In an exemplary embodiment, the internal connection terminal 26 may include a bump. However, exemplary embodiments of the present inventive concepts are not limited thereto. The internal connection terminal 26 is disposed on the semiconductor chip 24 (e.g., a lower surface of the semiconductor chip 24) and may be mounted on the first surface 10a of the circuit substrate 10. Referring to FIG. 1A, an active surface of the semiconductor chip 24 may be a bottom surface of the semiconductor chip 24 on which the internal connection terminal 26 is disposed.

In an exemplary embodiment, the semiconductor chip 24 may be a logic chip or a control chip. For example, in some exemplary embodiments, the semiconductor chip 24 may be a microcontroller (MC) or a microprocessor (MP). In an exemplary embodiment, the semiconductor chip 24 may be a memory chip, a buffer chip, a power management integrated circuit (PMIC) chip. In an exemplary embodiment, the semiconductor chip 24 may include at least one of a flash memory, dynamic random access memory (DRAM), static RAM (SRAM), erasable programmable read-only memory (EPROM), electrically erasable programmable ROM (EEPROM), flash EEPROM, magnetic RAM (MRAM), phase-change RAM (PRAM), or resistive RAM (RRAM). However, exemplary embodiments of the present inventive concepts are not limited thereto.

An external connection terminal 32 may be disposed on the second surface 10b of the circuit substrate 10. The external connection terminal 32 may include a signal connection terminal 28 and a ground connection terminal 30. In an exemplary embodiment, each of the above-described internal connection terminal 26 and the external connection terminal 32 may include a solder material, such as a solder ball, a solder bump, and solder paste, or include a metal having a spherical shape, a mesa shape, or a pin shape. However, exemplary embodiments of the present inventive concepts are not limited thereto. The internal interconnection 18 disposed in the circuit substrate 10 may be connected to the ground pad 14 and the external connection terminal 32 (e.g., the ground connection terminal 30). The internal interconnection 18 may also be connected to the signal pad and the external connection terminal 32 (e.g., the signal connection terminal 28).

An encapsulation layer 34 may be disposed on the circuit substrate 10 to encapsulate the semiconductor chip 24. The encapsulation layer 34 may be disposed on the circuit substrate 10 between the internal connection terminals 26 to surround the semiconductor chip 24. For example, as shown in the exemplary embodiment of FIG. 1A, the encapsulation layer 34 may surround upper, lower and side surfaces of the semiconductor chip 24. The encapsulation layer 34 may include an epoxy molding compound (EMC). The encapsulation layer 34 may protect the semiconductor chip 24.

A heat spreader 42 may surround the encapsulation layer 34 and dissipate heat generated by the semiconductor chip 24 that is transmitted to the encapsulation layer 34. For example, as shown in the exemplary embodiment of FIG. 1A, the heat spreader 42 may be disposed on lateral side surfaces and an upper surface (e.g., a top surface) of the encapsulation layer 34 and may dissipate heat generated by the semiconductor chip 24. The heat spreader 42 may include a side heat spreader 36 and a surface heat spreader 40. The side heat spreader 36 may be disposed on a top surface of the circuit substrate 10 and may directly contact the lateral side surfaces of the encapsulation layer 34. The side heat spreader 36 may be connected to the ground pad 14 and may directly contact the exposed surface of the ground pad 14 on the first surface 10a. The surface heat spreader 40 may be disposed on the upper surface of the encapsulation layer 34.

The side heat spreader 36 may extend to a higher level than an upper surface of the encapsulation layer 34. For example, a distance between an upper surface of the circuit substrate 10 to an upper surface of the side heat spreader 36 may be greater than the distance between an upper surface of the circuit substrate 10 to an upper surface of the encapsulation layer 34. The side heat spreader 36 may be connected to the ground pad 14. In an exemplary embodiment, the side heat spreader 36 may be integrally formed with the surface heat spreader 40. For example, the side heat spreader 36 and the surface heat spreader 40 may be formed as one integral body. Therefore, the surface heat spreader 40 may be connected to the ground pad 14 through the side spreader 36. However, exemplary embodiments of the present inventive concepts are not limited thereto.

The heat spreader 42 including the side heat spreader 36 and the surface heat spreader 40 may include a highly thermal conductive material, such as a metal material. For example, in an exemplary embodiment, the heat spreader 42 may include a material including at least one compound selected from copper (Cu), iron (Fe), nickel (Ni), cobalt (Co), tungsten (W), chromium (Cr), silver (Ag), gold (Au), platinum (Pt), tin (Sn), aluminum (Al), magnesium (Mg), zinc (Zn).

In an exemplary embodiment, the side heat spreader 36 may include a bulk metal layer. The bulk metal layer may refer to a planar metal layer that does not include any concave or convex structures. The surface heat spreader 40 may include a first pattern structure 39 having a plurality of first through grooves 38, which expose the upper surface of the encapsulation layer 34. The plurality of first through grooves 38 are spaced apart from each other (e.g., in a direction parallel to an upper surface of the circuit substrate 10).

Although the respective elements of the first pattern structure 39 are shown in the exemplary embodiment of FIG. 1A as having a constant height (e.g., distance from an upper surface of the encapsulation layer 34), in other exemplary embodiments, the respective elements included in the first pattern structure 39 may not have a constant height. In an exemplary embodiment in which a height of the first pattern structure 39 is not constant, the first pattern structure 39 may include a concave-convex structure. A planar shape (e.g., when viewed from above the semiconductor package 1P) of the first through grooves 38 may include a circular shape or a polygonal shape. However, shapes of the first through grooves 38 are not limited thereto and exemplary embodiments of the present inventive concepts may have different shapes. In addition, while the exemplary embodiment of FIG. 1A illustrates the elements of the first pattern structure 39 extending substantially perpendicular to an upper surface of the encapsulation layer 34, exemplary embodiments of the present inventive concepts are not limited thereto.

In an exemplary embodiment, thicknesses T1 and T2 of the side heat spreader 36 and surface heat spreader 40, respectively, may range from about 1 μm to about 300 μm. As shown in the exemplary embodiment of FIG. 1A, the side heat spreader 36 may have a thickness T1 that is a length extending in a direction parallel to an upper surface of the circuit substrate 10. The surface heat spreader 40 may have a thickness T2 that is a length extending in a direction perpendicular to the upper surface of the circuit substrate 10. In an exemplary embodiment, the heat spreader 42 may be formed using a physical-chemical deposition process, such as a physical vapor deposition (PVD) process or a spray coating process. However, exemplary embodiments of the present inventive concepts are not limited thereto. In an exemplary embodiment in which the heat spreader 42 is formed using a physical-chemical deposition process (e.g., a PVD process), the side heat spreader 36 may be formed to have a relatively smaller thickness T1 of about 2 μm to about 3 μm, and the surface heat spreader 40 may be formed to have a relatively larger thickness T2 of about 5 μm to 10 μm.

Hereinafter, a dissipation path of heat generated by the semiconductor chip 24 of the semiconductor package 1P will be described in detail with reference to the exemplary embodiment shown in FIG. 1B.

In the semiconductor package 1P, heat generated by the semiconductor chip 24 may be dissipated above the semiconductor chip 24 through the side heat spreader 36 in a first direction 44 (e.g., in a direction perpendicular to an upper surface of the circuit substrate 10 towards an upper surface of the semiconductor package 1P). In the semiconductor package 1P, heat generated by the semiconductor chip 24 may also be dissipated below the semiconductor chip 24 through the side heat spreader 36, the ground pad 14, the internal interconnection 18, and the ground connection terminal 30 of the external connection terminals 32 in a second direction 46 that is opposite the first direction 44. The semiconductor package 1P may discharge heat through the side heat spreader 36 in the second direction 46 to the circuit substrate 10.

Since the side heat spreader 36 is connected (e.g., either directly or indirectly) to each of the ground pad 14, the internal interconnection 18, and the ground connection terminal 30 of the external connection terminals 32, heat generated by the semiconductor chip 24 may be discharged through the side heat spreader 36 to the outside using a conduction method.

As shown in the exemplary embodiment of FIG. 1B, in the semiconductor package 1P, heat generated by the semiconductor chip 24 may be dissipated above the semiconductor chip 24 through the surface heat spreader 40 in a third direction 48 that is parallel to the first direction 44 and is spaced apart from the first direction 44 in a direction parallel to an upper surface of the circuit substrate 10. Since a surface area of the surface heat spreader 40 is increased due to the first through grooves 38, heat generated by the semiconductor chip 24 may be discharged through the surface heat spreader 40 to the outside using a convection method. While the heat is shown in FIG. 1B as being discharged in a first direction 44, second direction 46 and third direction 48 for convenience of explanation, exemplary embodiments of the present inventive concepts are not limited thereto and the heat may be discharged in various additional directions.

As described above, in the semiconductor package 1P according to an exemplary embodiment of the present inventive concepts, heat generated by the semiconductor chip 24 may be discharged by means of both a conduction method using the side heat spreader 36 and a convection method using the surface heat spreader 40. When heat generated by the semiconductor chip 24 is discharged using the conduction method, the heat may be discharged through the circuit substrate 10. Thus, the semiconductor package 1P according to the exemplary embodiment shown in FIG. 1B may efficiently discharge heat generated by the semiconductor chip 24.

FIG. 2A is a cross-sectional view of a semiconductor package 3P according to an exemplary embodiment of the present inventive concepts, and FIG. 2B is a cross-sectional view illustrating the flow of heat generated in a semiconductor chip 24 of the semiconductor package 3P of FIG. 2A according to an exemplary embodiment of the present inventive concepts.

The semiconductor package 3P shown in the exemplary embodiments of FIGS. 2A and 2B may be the same as the semiconductor package 1P shown in the exemplary embodiments of FIGS. 1A and 1B except for the surface heat spreader 40a included in the heat spreader 42a. In FIGS. 2A and 2B, a description of the same elements shown in FIGS. 1A and 1B will be omitted or briefly presented for convenience of explanation.

The semiconductor package 3P may include the heat spreader 42a, which surrounds an encapsulation layer 34 and dissipates heat generated by the semiconductor chip 24. The heat spreader 42a may include the same material as the heat spreader 42 of the exemplary embodiments of FIGS. 1A and 1B. The heat spreader 42a may include a side heat spreader 36 and a surface heat spreader 40a. The side heat spreader 36 may be disposed on a top surface of a circuit substrate 10 and may directly contact lateral side surfaces of the encapsulation layer 34. The side heat spreader 36 may be connected to the ground pad 14. The surface heat spreader 40a may be disposed on an upper surface of the encapsulation layer 34. The side heat spreader 36 may directly contact the exposed surface of the ground pad 14 on the first surface 10a to connect to the ground pad 14. In an exemplary embodiment, the side heat spreader 36 may be integrally disposed with the surface heat spreader 40a.

The surface heat spreader 40a may include a first base layer 50 and a second pattern structure 54 that is disposed on the first base layer 50. The first base layer 50 may be disposed on the upper surface of the encapsulation layer 34, and the second pattern structure 54 may have a plurality of first recess grooves 52, which expose an upper surface of the first base layer 50. The plurality of first recess grooves 52 are spaced apart from each other (e.g., in a direction parallel to an upper surface of the circuit substrate 10). The second pattern structure 54 may include a concave-convex structure.

In an exemplary embodiment, thicknesses T1 and T2 of the side heat spreader 36 and the surface heat spreader 40a, respectively, may range from about 1 μm to about 300 μm. In an exemplary embodiment, a thickness T3 of the second pattern structure 54 (e.g., length above the upper surface of the first base layer 50 in a direction perpendicular to an upper surface of the circuit substrate 10) included in the surface heat spreader 40a may be less than a thickness T2 of the surface heat spreader 40 shown in FIGS. 1A and 1B. In an exemplary embodiment, the thickness T3 of the second pattern structure 54 may range from about 2 μm to about 5 μm. In an exemplary embodiment, the planar shape of the first recess grooves 52 may include a circular shape or a polygonal shape. However, exemplary embodiments of the present inventive concepts are not limited thereto and the planar shapes of the first recess grooves 52 may have various other shapes.

Hereinafter, a dissipation path of heat generated by the semiconductor chip 24 of the semiconductor package 3P will be described in detail with reference to FIG. 2B.

In the semiconductor package 3P, as described above, heat generated by the semiconductor chip 24 may be dissipated through the side heat spreader 36 in each of the first direction 44 and the second direction 46 above and below a level of the semiconductor chip 24, respectively. In the semiconductor package 3P shown in the exemplary embodiments of FIGS. 2A-2B, heat generated by the semiconductor chip 24 may be discharged through the side heat spreader 36 to the outside using a conduction method.

In the semiconductor package 3P, heat generated by the semiconductor chip 24 may be dissipated above the semiconductor chip 24 through the surface heat spreader 40a in a fourth direction 48a that is parallel to the first direction 44 and the second direction 46 and is spaced apart from the first direction 44 in a direction parallel to an upper surface of the circuit substrate 10. In the semiconductor package 3P, heat generated by the semiconductor chip 24 may be dissipated in the fourth direction 48a through the surface heat spreader 40a, that is, the first base layer 50 and the second pattern structure 54 having the first recess grooves 52. Since a surface area of the surface heat spreader 40a is increased due to the first recess grooves 52, heat generated by the semiconductor chip 24 may be discharged through the surface heat spreader 40a to the outside using a convection method.

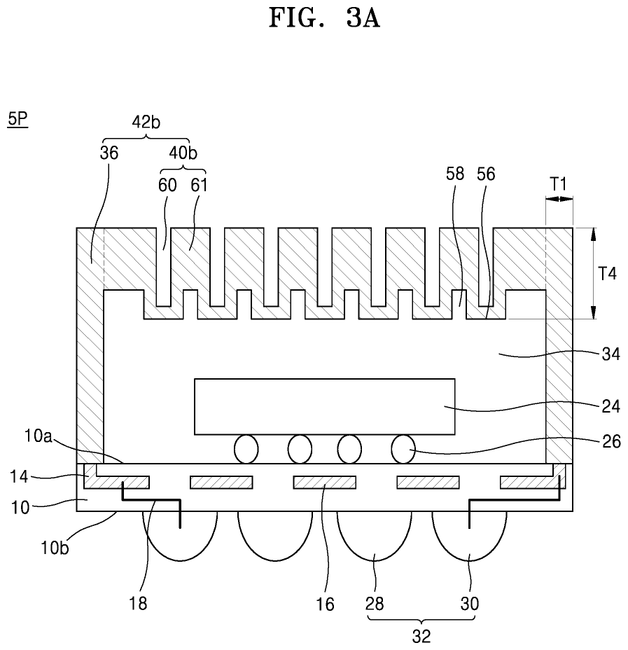

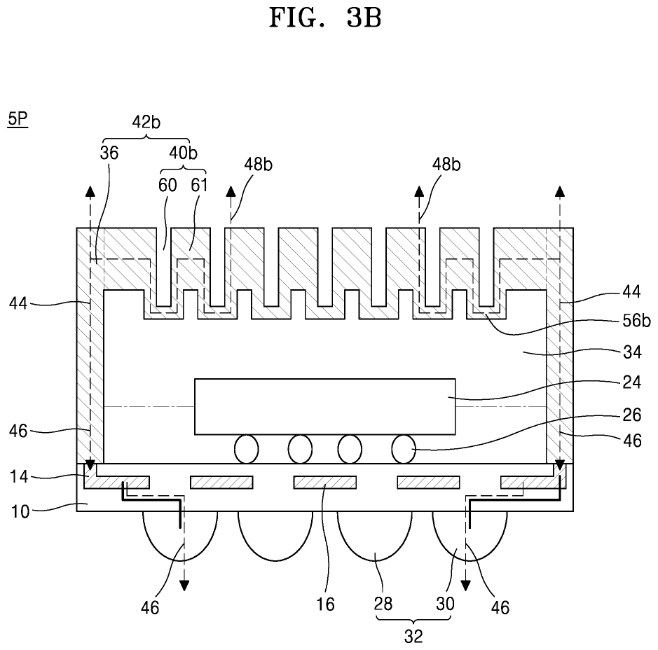

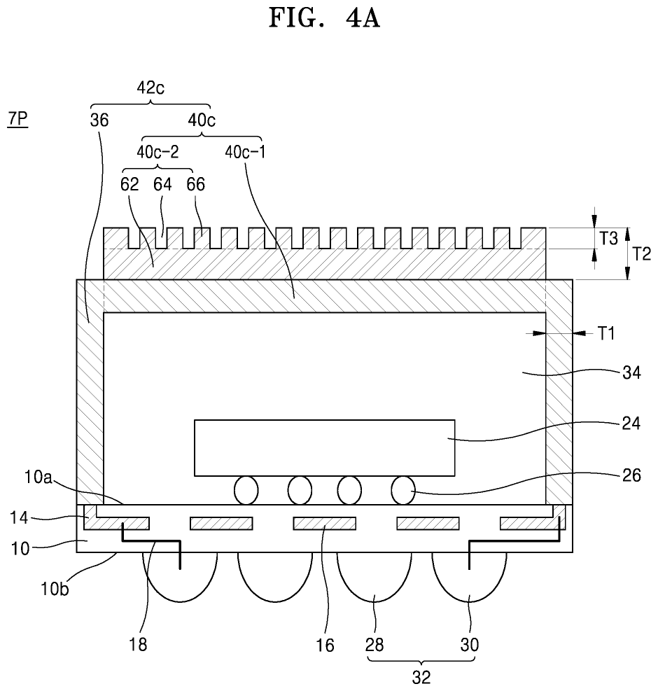

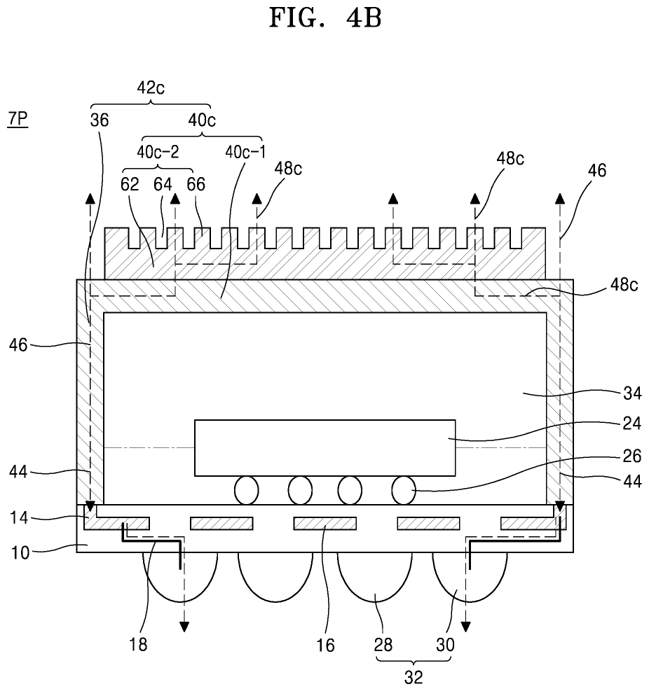

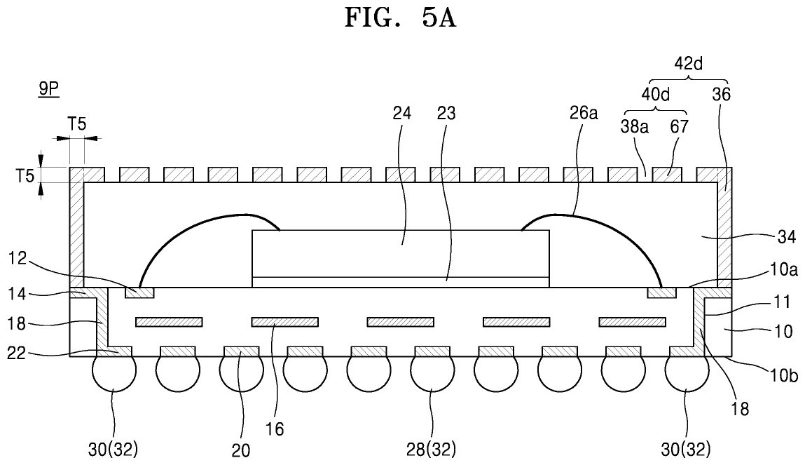

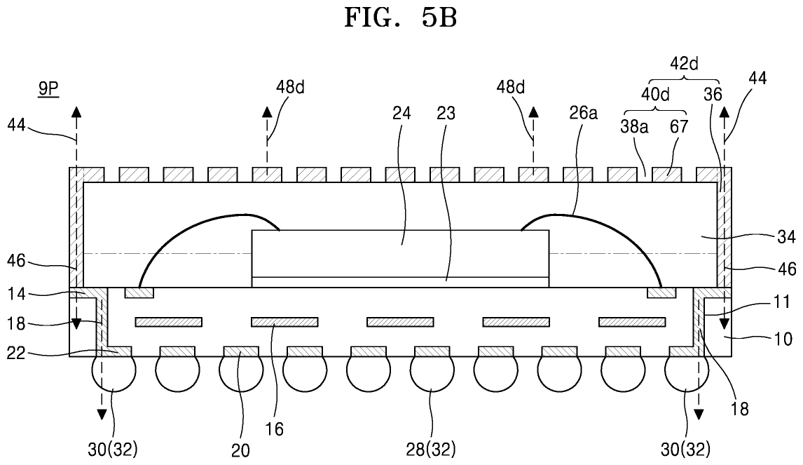

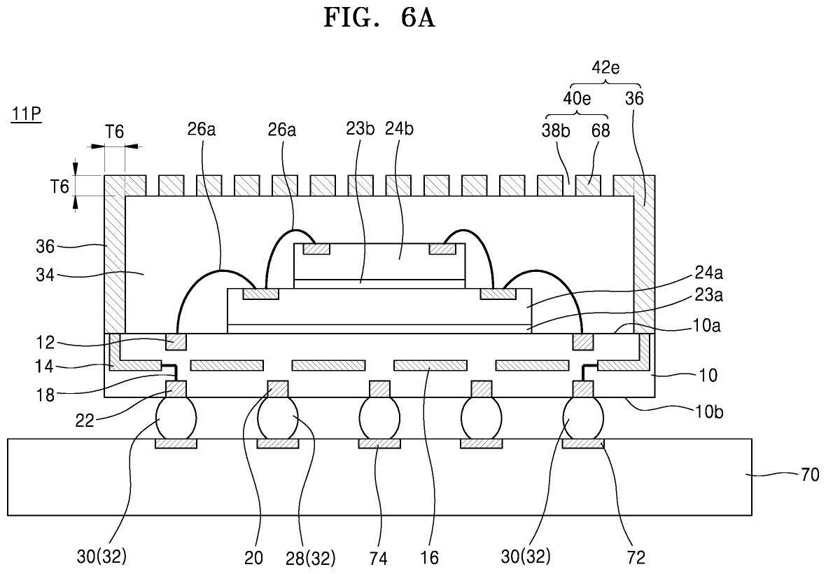

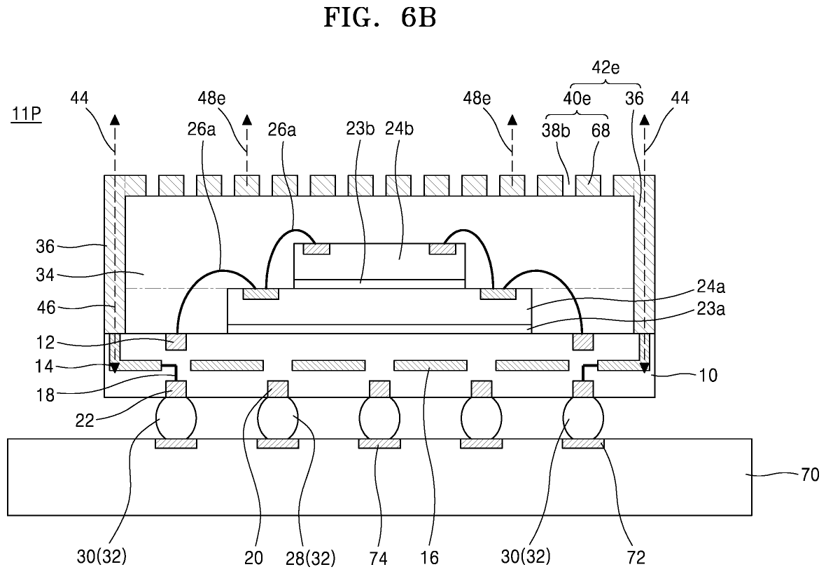

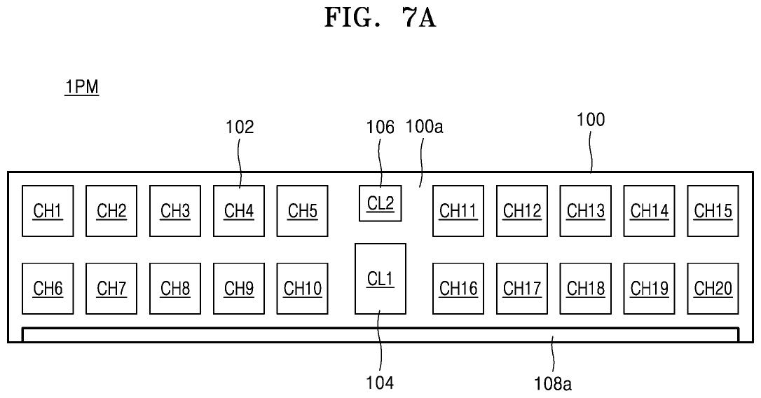

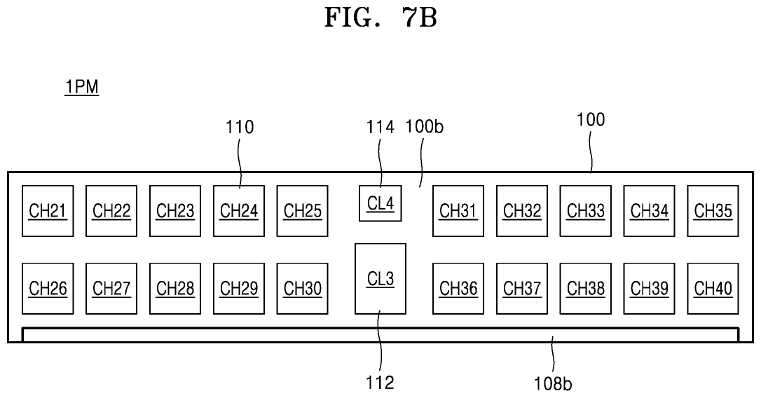

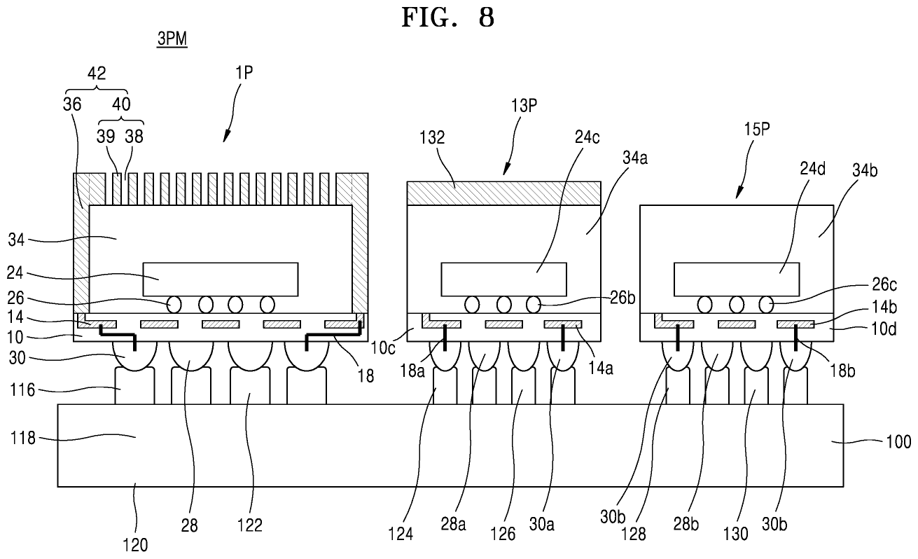

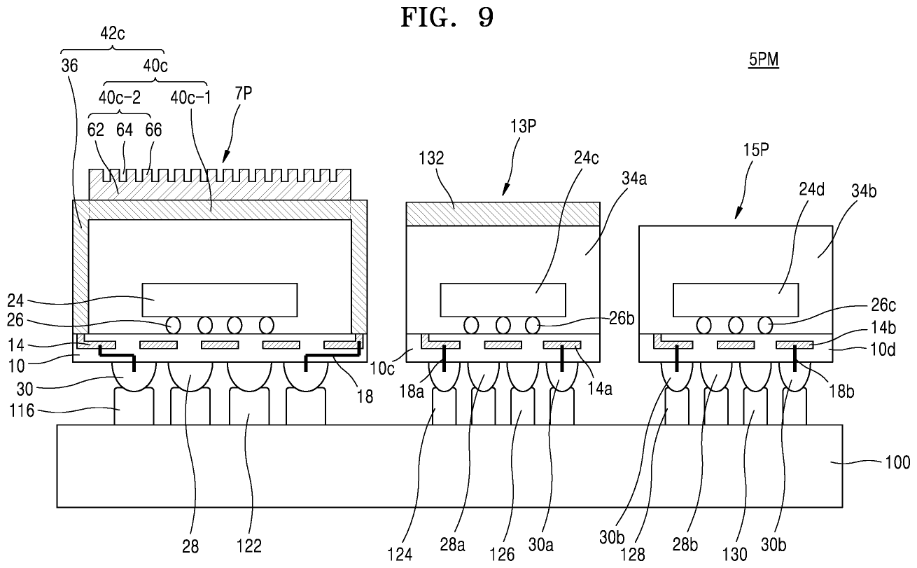

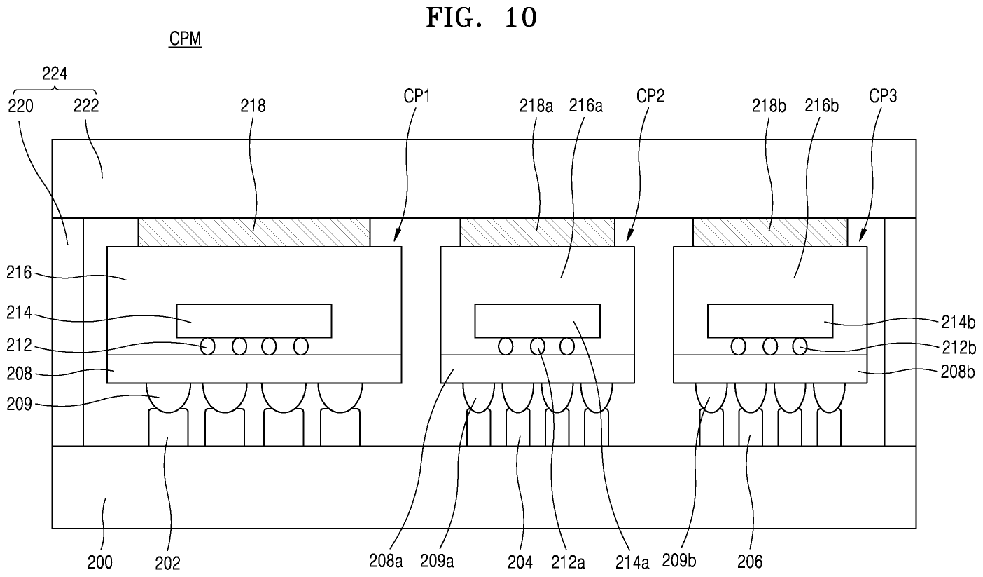

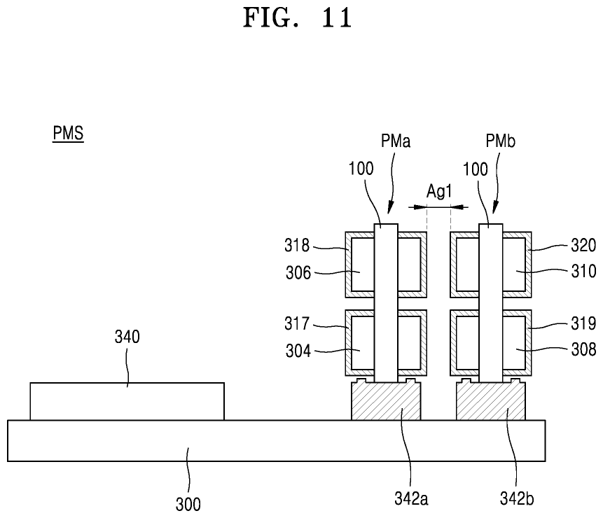

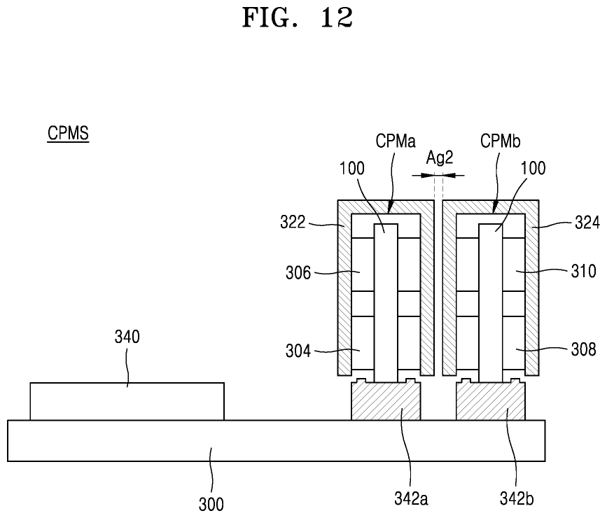

FIG. 3A is a cross-sectional view of a semiconductor package 5P according to an exemplary embodiment of the present inventive concepts, and FIG. 3B is a cross-sectional view illustrating the flow of heat generated in a semiconductor chip 24 of the semiconductor package 5P of FIG. 3A according to an exemplary embodiment of the present inventive concepts.

The semiconductor package 5P shown in FIGS. 3A and 3B may be the same as the semiconductor packages 1P and 3P shown in FIGS. 1A, 1B, 2A, and 2B except for a surface heat spreader 40b included in a heat spreader 42b. In the exemplary embodiments of FIGS. 3A and 3B, the same description as with reference to FIGS. 1A, 1B, 2A, and 2B will be omitted or briefly presented for convenience of explanation.

The semiconductor package 5P may include a heat spreader 42b, which surrounds an encapsulation layer 34 and dissipates heat generated by the semiconductor chip 24. The heat spreader 42b may include the same material as the heat spreader 42 of FIGS. 1A and 1B. The heat spreader 42b may include a side heat spreader 36 and a surface heat spreader 40b. The side heat spreader 36 may be disposed on a top surface of a circuit substrate 10 and lateral side surfaces of the encapsulation layer 34 and may be connected to the ground pad 14 (e.g., connected to the ground pad 14 by directly contacting the exposed surface of the ground pad 14 on the first surface 10a of the circuit substrate 10). The surface heat spreader 40b may be disposed on the upper surface of the encapsulation layer 34. In an exemplary embodiment, the side heat spreader 36 may be integrally formed with the surface heat spreader 40b.

The semiconductor package 5P may include a third pattern structure 58, which is located in an upper portion of the encapsulation layer 34 and includes a plurality of second recess grooves 56 disposed between the third pattern structures 58. The plurality of second recess grooves 56 may be formed inward (e.g., in a direction parallel to the second direction 46) and are spaced apart from each other. The second recess grooves 56 and the third pattern structure 58 may be referred to as additional recess grooves and an additional pattern structure, respectively. In an exemplary embodiment, the third pattern structure 58 may include the same material as the encapsulation layer 34.

The surface heat spreader 40b may be disposed on the third pattern structure 58 including the second recess grooves 56. The surface heat spreader 40b may include a fourth pattern structure 61 disposed on the third pattern structure 58 and in portions of the second recess grooves 56. The fourth pattern structure 61 may have third recess grooves 60 which overlap (e.g., in a thickness direction of the semiconductor package 5P) the second recess grooves 56. The fourth pattern structure 61 may have a concave-convex structure. A width of the third recess grooves 60 (e.g., length in a direction parallel to an upper surface of the circuit substrate 10) may be less than a width of the second recess grooves 56. The surface heat spreader 40b may not entirely fill the second recess grooves 56 due to the third recess grooves 60.

In an exemplary embodiment, the heat spreader 42b may have thicknesses T1 and T4 of the side heat spreader 36 and the surface heat spreader 40b, respectively, of about 1 μm to about 300 μm. A thickness T4 of the fourth pattern structure 61 included in the surface heat spreader 40b may be greater than the thickness T2 of the surface heat spreader 40 shown in the exemplary embodiments of FIGS. 1A and 1B. For example, in an exemplary embodiment, the thickness T4 of the fourth pattern structure 61 may range from about 7 μm to about 12 μm. However, exemplary embodiments of the present inventive concepts are not limited thereto and the planar shape of the third recess grooves 60 may have various other shapes.

Hereinafter, a dissipation path of heat generated by the semiconductor chip 24 of the semiconductor package 5P will be described in detail with reference to FIG. 3B.

In the semiconductor package 5P, as described above, heat generated by the semiconductor chip 24 may be dissipated through the side heat spreader 36 in each of a first direction 44 and a second direction 46 above and below a level of the semiconductor chip 24, respectively. In the semiconductor package 5P shown in the exemplary embodiments of FIGS. 3A-3B, heat generated by the semiconductor chip 24 may be discharged through the side heat spreader 36 to the outside (e.g., through the circuit substrate 10) using a conduction method.

In the semiconductor package 5P, heat generated by the semiconductor chip 24 may be dissipated above the semiconductor chip 24 through the surface heat spreader 40b in a fifth direction 48b that is parallel to the first direction 44 and is spaced apart from the first direction in a direction parallel to an upper surface of the circuit substrate 10. In the semiconductor package 5P, heat generated by the semiconductor chip 24 may be dissipated in the fifth direction 48b through the fourth pattern structure 61, which is included in the surface heat spreader 40b and includes the third recess grooves 60. Since a surface area of the surface heat spreader 40b is increased due to the third recess grooves 60, heat generated by the semiconductor chip 24 may be discharged through the surface heat spreader 40b to the outside using a convection method.

FIG. 4A is a cross-sectional view of a semiconductor package 7P according to an exemplary embodiment of the present inventive concepts, and FIG. 4B is a cross-sectional view illustrating the flow of heat generated in a semiconductor chip 24 of the semiconductor package 7P of FIG. 4A according to an exemplary embodiment of the present inventive concepts.

The semiconductor package 7P shown in the exemplary embodiments of FIGS. 4A and 4B may be the same as the above-described semiconductor packages 1P, 3P, and 5P for a surface heat spreader 40c included in a heat spreader 42c. In the exemplary embodiments of FIGS. 4A and 4B, the same description as those of the above-described semiconductor packages 1P, 3P, and 5P will be omitted or briefly presented for convenience of explanation.

The semiconductor package 7P may include a heat spreader 42c, which surrounds an encapsulation layer 34 and dissipates heat generated by the semiconductor chip 24. The heat spreader 42c may include the same material as the heat spreader 42 of the exemplary embodiments of FIGS. 1A and 1B. The heat spreader 42c may include a side heat spreader 36 and a surface heat spreader 40c. The side heat spreader 36 may be disposed on a top surface of a circuit substrate 10 and lateral side surfaces of the encapsulation layer 34 and may be connected to a ground pad 14. The surface heat spreader 40c may be disposed on an upper surface of the encapsulation layer 34. The side heat spreader 36 may be connected to the ground pad 14 (e.g., connected to the ground pad 14 by directly contacting the exposed surface of the ground pad 14 on the first surface 10a of the circuit substrate 10).

The surface heat spreader 40c may include a first surface heat spreader 40c-1 and a second surface heat spreader 40c-2 disposed on the first surface heat spreader 40c-1. The first surface heat spreader 40c-1 may be formed on the upper surface of the encapsulation layer 34, and the second surface heat spreader 40c-2 may be formed on the upper surface of the first surface heat spreader 40c-1. In an exemplary embodiment, the second surface heat spreader 40c-2 may be a film type. In an exemplary embodiment, the side heat spreader 36 may be integrally formed with the first surface heat spreader 40c-1. A thickness T1 of the first surface heat spreader 40c-1 may be equal to a thickness of the side heat spreader 36 described above with respect to the exemplary embodiments of FIGS. 1A-1B. In an exemplary embodiment, the side heat spreader 36 may not be integrally formed with the second surface heat spreader 40c-2. For example, the side heat spreader 36 and the second surface heat spreader 40c-2 may not be one body.

The second surface heat spreader 40c-2 may include a second base layer 62 and a fifth pattern structure 66. The second base layer 62 may be disposed on an upper surface of the first surface heat spreader 40c-1, and the fifth pattern structure 66 may have a plurality of fourth recess grooves 64, which expose the upper surface of the second base layer 62 and are spaced apart from each other (e.g., in a direction parallel to an upper surface of the circuit substrate 10). The fifth pattern structure 66 may include a concave-convex structure. The second base layer 62 and the fifth pattern structure 66 may together have the above-described thickness T2. The fifth pattern structure 66 may have the thickness T3 as described with respect to the exemplary embodiment shown in FIG. 2A. A planar shape of the fourth recess grooves 64 may include a circular shape or a polygonal shape. However, exemplary embodiments of the present inventive concepts are not limited thereto and the planar shapes of the fourth recess grooves 64 may have various other shapes.

However, exemplary embodiments of the present inventive concepts are not limited thereto and the planar shapes of the first recess grooves 52 may have various other shapes.

Hereinafter, a dissipation path of heat generated by the semiconductor chip 24 of the semiconductor package 7P will be described in detail with reference to FIG. 4B.

In the semiconductor package 7P, as described above, heat generated by the semiconductor chip 24 may be dissipated through the side heat spreader 36 in each of a first direction 44 and a second direction 46 above and below a level of the semiconductor chip 24, respectively. In the semiconductor package 7P, heat generated by the semiconductor chip 24 may be discharged through the side heat spreader 36 to the outside using a conduction method.

In the semiconductor package 7P, heat generated by the semiconductor chip 24 may be dissipated above the semiconductor chip 24 through the first surface heat spreader 40c-1 and the second surface heat spreader 40c-2 in a sixth direction 48c that is parallel to the first direction 44 and is spaced apart from the first direction 44 in a direction parallel to an upper surface of the circuit substrate 10. Since a surface area of the surface heat spreader 40c is increased due to the fourth recess grooves 64, heat generated by the semiconductor chip 24 may be discharged through the surface heat spreader 40c to the outside using a convection method.

FIG. 5A is a cross-sectional view of a semiconductor package 9P according to an exemplary embodiment of the present inventive concepts, and FIG. 5B is a cross-sectional view illustrating the flow of heat generated in a semiconductor chip 24 of the semiconductor package 9P of FIG. 5A according to an exemplary embodiment of the present inventive concepts.

The semiconductor package 9P may be the same as the above-described semiconductor packages 1P, 3P, 5P, and 7P except for a surface heat spreader 40d included in a heat spreader 42d, a connection relationship between the semiconductor chip 24 and a circuit substrate 10, and a connection relationship between a ground pad 14 and an external connection terminal 32. In the exemplary embodiment of FIGS. 5A and 5B, the same description as those of the above-described semiconductor packages 1P, 3P, 5P, and 7P will be omitted or briefly presented for convenience of explanation.

The semiconductor package 9P may include the semiconductor chip 24, which is mounted on the circuit substrate 10 with an adhesive layer 23 therebetween. The semiconductor chip 24 may be connected to a signal pad 12 located on the circuit substrate 10 by a bonding wire 26a. Since the semiconductor chip 24 is connected to the circuit substrate 10 by the bonding wire 26a, a width of the semiconductor package 9P (e.g., length in a direction parallel to an upper surface of the circuit substrate 10) may be greater than those of the above-described semiconductor packages 1P, 3P, 5P, and 7P. The signal pad 12 may be connected to a signal connection pad 20 and the external connection terminal 32 (e.g., a signal connection terminal 28) through an internal interconnection.

The ground pad 14 may be connected to the semiconductor chip 24 using a bonding wire. The ground pad 14 may be connected to a ground connection pad 22 disposed on a lower surface of the circuit substrate 10 and the external connection terminal 32 (e.g., a ground connection terminal 30) through an internal interconnection 18. The internal interconnection 18 may be an internal through interconnection, which is disposed inside a through hole 11 that is formed through the circuit substrate 10 and which extends through an entire thickness of the circuit substrate 10.

The semiconductor package 9P may include the heat spreader 42d, which surrounds an encapsulation layer 34 and dissipates heat generated by the semiconductor chip 24. The heat spreader 42d may include the same material as the heat spreader 42 shown in the exemplary embodiments of FIGS. 1A and 1B. The heat spreader 42d may include a side heat spreader 36 and a surface heat spreader 40d. The side heat spreader 36 may be disposed on a top surface of the circuit substrate 10 and lateral side surfaces of the encapsulation layer 34 and may be connected to the ground pad 14. The surface heat spreader 40d may be formed on an upper surface of the encapsulation layer 34. The side heat spreader 36 may be connected to the ground pad 14.

The surface heat spreader 40d may include a sixth pattern structure 67 having a plurality of second through grooves 38a, which expose the upper surface of the encapsulation layer 34 and are spaced apart from each other (e.g., in a direction parallel to an upper surface of the circuit substrate 10). A planar shape of the second through grooves 38a may include a circular shape or a polygonal shape. However, exemplary embodiments of the present inventive concepts are not limited thereto and the planar shapes of the second through grooves 38a may have various other shapes. In an exemplary embodiment, the side heat spreader 36 may be integrally formed with the surface heat spreader 40d. In an exemplary embodiment, a thickness T5 of the heat spreader 42d may range from about 1 μm to about 300 μm. In an exemplary embodiment, the thickness T5 of the heat spreader 42d may range from about 10 μm to about 20 μm. As shown in the exemplary embodiment of FIG. 5A, the surface heat spreader 40d may have the same thickness T5 as the side heat spreader 36.

Hereinafter, a dissipation path of heat generated by the semiconductor chip 24 of the semiconductor package 9P will be described in detail with reference to FIG. 5B.

In the semiconductor package 9P, as described above, heat generated by the semiconductor chip 24 may be dissipated through the side heat spreader 36 in each of a first direction 44 and a second direction 46 above and below a level of the semiconductor chip 24, respectively. In the semiconductor package 9P, heat generated by the semiconductor chip 24 may be discharged through the side heat spreader 36 to the outside using a conduction method.

In the semiconductor package 9P, heat generated by the semiconductor chip 24 may be dissipated above the semiconductor chip 24 through the sixth pattern structure 67 of the surface heat spreader 40d in a seventh direction 48d that is parallel to the first direction 44 and is spaced apart from the first direction 44 in a direction parallel to an upper surface of the circuit substrate 10. Since a surface area of the surface heat spreader 40d is increased due to the second through grooves 38a, heat generated by the semiconductor chip 24 may be discharged through the sixth pattern structure 67 of the surface heat spreader 40d to the outside using a convection method.

FIG. 6A is a cross-sectional view of a semiconductor package 11P according to an exemplary embodiment of the present inventive concepts, and FIG. 6B is a cross-sectional view illustrating the flow of heat generated by a plurality semiconductor chips of the semiconductor package 11P of FIG. 6A according to an exemplary embodiment of the present inventive concepts.

The semiconductor package 11P shown in the exemplary embodiments of FIGS. 6A and 6B may be the same as the above-described semiconductor packages 1P, 3P, 5P, 7P, and 9P except that the semiconductor package 11P further includes a plurality of semiconductor chips (e.g., first and second semiconductor chips 24a and 24b) and an additional circuit substrate 70 and includes a heat spreader 42e having a different thickness. The semiconductor package 11P may be a System-in-Package (SiP). In the exemplary embodiments of FIGS. 6A and 6B, the same description as those of the above-described semiconductor packages 1P, 3P, 5P, 7P, and 9P will be omitted or briefly presented for convenience of explanation.

The semiconductor package 11P may include the first semiconductor chip 24a, which is mounted on a circuit substrate 10 with a first adhesive layer 23a therebetween. For example, as shown in the exemplary embodiment of FIG. 6A, an upper surface of the adhesive layer 23a may directly contact a lower surface of the first semiconductor chip 24a. A lower surface of the adhesive layer 24a may directly contact an upper surface of the circuit substrate 10. The second semiconductor chip 24b may be mounted on (e.g., disposed on) the first semiconductor chip 24a with a second adhesive layer 23b therebetween. For example, as shown in the exemplary embodiment of FIG. 6A, an upper surface of the second adhesive layer 23b may directly contact a lower surface of the second semiconductor chip 24b and a lower surface of the second adhesive layer 23b may directly contact an upper surface of the first semiconductor chip 24a.

The first semiconductor chip 24a and the second semiconductor chip 24b may be connected to a signal pad 12 of the circuit substrate 10 by a bonding wire 26a. The signal pad 12 may be connected to a signal connection pad 20 on a lower surface of the circuit substrate 10 and an external connection terminal 32 between the circuit substrate 10 and the additional circuit substrate 70 (e.g., a signal connection terminal 28) by an internal interconnection. A ground pad 14 may be connected to the first and second semiconductor chips 24a and 24b by a bonding wire. The ground pad 14 may be connected to a ground connection pad 22 and the external connection terminal 32 (e.g., a ground connection terminal 30) by an internal interconnection 18. The encapsulation layer 34 may encapsulate the first semiconductor chip 24a and second semiconductor chip 24b (e.g., surround lateral side surfaces and upper surfaces of the first semiconductor chip 24a and second semiconductor chip 24b).

The semiconductor package 11P may include a heat spreader 42e, which surrounds the encapsulation layer 34 and dissipates heat generated by the first and second semiconductor chips 24a and 24b. The heat spreader 42e may include the same material as the heat spreader 42 shown in FIGS. 1A and 1B. The heat spreader 42e may include a side heat spreader 36 and a surface heat spreader 40e. The side heat spreader 36 may be formed on lateral side surfaces of the encapsulation layer 34 and may be connected to the ground pad 14. The surface heat spreader 40e may be formed on an upper surface of the encapsulation layer 34. The side heat spreader 36 may be connected to the ground pad 14 through the internal interconnection 18.

In the semiconductor package 11P, the external connection terminal 32 may be connected to additional connection pads 72 and 74 of the additional circuit substrate 70. For example, the additional connection pads 72 and 74 may be disposed on an upper surface of the additional circuit substrate 70. The ground connection terminal 30 of the external connection terminal 32 may be connected to the additional ground pad of the additional connection pads 72 and 74. The signal connection terminal 28 of the external connection terminal 32 may be connected to the additional signal pad 74 of the additional connection pads 72 and 74.

The surface heat spreader 40e may include a seventh pattern structure 68 having a plurality of third through grooves 38b, which expose the upper surface of the encapsulation layer 34 and are spaced apart from each other (e.g., in a direction parallel to an upper surface of the circuit substrate 10). A planar shape of the third through grooves 38b may include a circular shape or a polygonal shape. However, exemplary embodiments of the present inventive concepts are not limited thereto and the planar shapes of the third through grooves 38b may have various other shapes. In an exemplary embodiment, the side heat spreader 36 may be integrally formed with the surface heat spreader 40e.

In an exemplary embodiment, a thickness T6 of the heat spreader 42e may range from about 1 μm to about 300 sm. For example, the thickness T6 of the heat spreader 42e may range from about 10 μm to about 20 μm. The thickness T6 of the heat spreader 42e may be greater than the thickness T5 of the heat spreader 42d shown in the exemplary embodiments of FIGS. 5A and 5B. The surface heat spreader 40e may have the same thickness T6 as the side heat spreader 36.

Hereinafter, a dissipation path of heat generated by the first and second semiconductor chips 24a and 24b of the semiconductor package 11P will be described in detail with reference to FIG. 6B.

In the semiconductor package 11P, as described above, heat generated by the first and second semiconductor chips 24a and 24b may be dissipated through the side heat spreader 36 in each of a first direction 44 and a second direction 46 above and below a level of the semiconductor package 11P, respectively. In the semiconductor package 11P, heat generated by the first and second semiconductor chips 24a and 24b may be transferred through the side heat spreader 36 and discharged through the circuit substrate 10 and the additional circuit substrate 70 to the outside using a conduction method.

In the semiconductor package 11P, heat generated by the first and second semiconductor chips 24a and 24b may also be dissipated above the first and second semiconductor chips 24a and 24b through a seventh pattern structure 68 of the surface heat spreader 40e in an eighth direction 48e that is parallel to the first direction 44 and is spaced apart from the first direction 44 in a direction parallel to an upper surface of the circuit substrate 10. Since a surface area of the surface heat spreader 40e is increased due to the third through grooves 38b, heat generated by the first and second semiconductor chips 24a and 24b may be discharged through the seventh pattern structure 68 of the surface heat spreader 40e to the outside using a convection method.

FIGS. 7A and 7B are plan views of a semiconductor package module 1PM according to an exemplary embodiment of the present inventive concepts.

As shown in the exemplary embodiment of FIG. 7A, the semiconductor package module 1PM may include a plurality of semiconductor packages, for example, first to 20^{th} semiconductor packages 102, a 21^{st} semiconductor package 104, and a 22^{nd} semiconductor package 106, which are mounted on a first surface 100a of a module circuit substrate 100. The first to 22^{nd} semiconductor packages 102, 104, and 106 may include any of the above-described semiconductor packages 1P, 3P, 5P, 7P, 9P, and 11P as shown in the exemplary embodiments of FIGS. 1A-6B. In an exemplary embodiment, the module circuit substrate 100 may be a PCB. The semiconductor package module 1PM may include a first connection unit 108a, which is formed on the first surface 100a of the module circuit substrate 100 to connect with an external device.

In an exemplary embodiment, the first to 20^{th} semiconductor packages 102 may include first to 20^{th} memory semiconductor packages. The first to 20^{th} semiconductor packages 102 may include first to 20^{th} memory semiconductor chips CH1 to CH20, respectively. In an exemplary embodiment, the 21^{st} semiconductor package 104 and the 22^{nd} semiconductor package 106 may be control semiconductor packages configured to control the first to 20^{th} semiconductor packages 102.

The 21^{st} semiconductor package 104 and the 22^{nd} semiconductor package 106 may respectively include a first control semiconductor chip CL1 and a second control semiconductor chip CL2 configured to control the first to 20^{th} memory semiconductor chips CH1 to CH20. In an exemplary embodiment, the first control semiconductor chip CL1 and the second control semiconductor chip CL2 may be logic chips, for example, buffer chips or PMIC chips.

As shown in the exemplary embodiment of FIG. 7B, the semiconductor package module 1PM may include a plurality of semiconductor packages, for example, 21^{st} to 40^{th} semiconductor packages 110, a 41^{st} semiconductor package 112, and a 42^{nd} semiconductor package 114, which are mounted on a second surface 100b of the module circuit substrate 100. The 21^{st} to 42^{nd} semiconductor packages 110, 112, and 114 may include any of the above-described semiconductor packages 1P, 3P, 5P, 7P, 9P, and 11P. The semiconductor package module 1PM may include a second connection unit 108b, which is formed on the second surface 100b of the module circuit substrate 100 to connect with an external device.

In an exemplary embodiment, the 21^{st} to 40^{th} semiconductor packages 110 may include 21^{st} to 40^{th} memory semiconductor packages. The 21^{st} to 40^{th} semiconductor packages 110 may include 21^{st} to 40^{th} memory semiconductor chips CH21 to CH40, respectively. The 41^{st} semiconductor package 112 and the 42^{nd} semiconductor package 114 may be control semiconductor packages configured to control the 21^{st} to 40^{th} semiconductor packages 110.

The 41^{st} semiconductor package 112 and the 42^{nd} semiconductor package 114 may respectively include a third control semiconductor chip CL3 and a fourth control semiconductor chip CL4 configured to control the 21^{st} to 40^{th} memory semiconductor chips CH21 to CH40. In an exemplary embodiment, the third control semiconductor chip CL3 and the fourth control semiconductor chip CL4 may be logic chips, for example, buffer chips or PMIC chips.

Although the exemplary embodiments of FIGS. 7A and 7B illustrate an example in which the semiconductor package module 1PM include semiconductor packages mounted on both the first and second surfaces 100a and 100b of the module circuit substrate 100, in another exemplary embodiment, semiconductor packages may be mounted on only one of the first and second surfaces 100a or 100b of the module circuit substrate 100.

In an exemplary embodiment, the semiconductor package module 1PM may include a memory semiconductor package module. The memory semiconductor package module may be a single in-line memory module (SIMM) in which the semiconductor packages 102, 104, 106, 110, 112, and 114 are mounted on only one surface of the first and second surfaces 100a, 100b of the module circuit substrate 100 as shown in any one of FIGS. 7A and 7B. In another exemplary embodiment, the semiconductor package module 1PM may be a dual in-line memory module (DIMM) in which the semiconductor packages 102, 104, 106, 110, 112, and 114 are mounted on both surfaces of the first and second surfaces 100a, 100b of the module circuit substrate 100.

Although the exemplary embodiments of FIGS. 7A and 7B illustrate an example in which the semiconductor package module 1PM is the memory semiconductor package module, in other exemplary embodiments, the semiconductor package module 1PM may be a logic semiconductor package module instead of the memory semiconductor package module. Further the number of semiconductor packages on each of the first and second surfaces 100a and 100b of the module circuit substrate 100 and the numbers of control semiconductor chips and memory semiconductor chips and/or logic semiconductor chips may vary and are not limited to the exemplary embodiments of FIGS. 7A-7B.

FIG. 8 is a cross-sectional view of a semiconductor package module 3PM according to an exemplary embodiment of the present inventive concepts.

The semiconductor package module 3PM may include a plurality of semiconductor packages, for example, first to third semiconductor packages 1P, 13P, and 15P, which are mounted on a module circuit substrate 100. In an exemplary embodiment, the module circuit substrate 100 may include a PCB. Although FIG. 8 illustrates an example in which the semiconductor packages 1P, 13P, and 15P are arranged on only a first surface of the module circuit substrate 100 (e.g., an upper surface of the module circuit substrate 100), a plurality of semiconductor packages may be arranged also on a second surface of the module circuit substrate 100 (e.g., a lower surface of the module circuit substrate 100), which is opposite to the first surface. Furthermore, in another exemplary embodiment, the semiconductor packages 1P, 13P, and 15P may be arranged only on the second surface of the module circuit substrate 100.

The first to third semiconductor packages 11P, 13P, and 15P may be disposed on the module circuit substrate 100 and spaced apart from each other (e.g., in a direction parallel to an upper surface of the module circuit substrate 100). The first to third semiconductor packages 1P, 13P, and 15P may be spaced apart from each other and may individually dissipate heat on the module circuit substrate 100. For example, the first to third semiconductor packages 1P, 13P, and 15P may not collectively dissipate heat.

Accordingly, the first to third semiconductor packages 1P, 13P, and 15P may not be affected by heat generated from each other. For example, in an exemplary embodiment in which the first semiconductor package 1P is a control semiconductor package configured to control the second semiconductor package 13P and the third semiconductor package 15P, even if the first semiconductor package 1P generates a large amount of heat, the heat generated by the first semiconductor package 1P may not affect the second semiconductor package 13P and the third semiconductor package 15P.

Hereinafter, connection relationships between the first to third semiconductor packages 1P, 13P, and 15P and the module circuit substrate 100 will be described.

In the first to third semiconductor packages 1P, 13P, and 15P, module ground pads 116, 124, and 128 disposed on an upper surface of the module circuit substrate 100 may be connected to ground connection terminals 30, 30a, and 30b disposed on lower surfaces of the circuit substrate 10, the second circuit substrate 10c and the third circuit substrate 10d, respectively. In the first to third semiconductor packages 1P, 13P, and ISP, module signal pads 122, 126, and 130 may be connected to signal connection terminals 28, 28a, and 28b disposed on lower surfaces of the circuit substrate 10, the second circuit substrate 10c and the third circuit substrate 10d, respectively.

As described above with reference to the exemplary embodiments of FIGS. 1A and 1B, the first semiconductor package 1P may dissipate heat through a heat spreader 42. The first semiconductor package 1P may discharge heat generated by a semiconductor chip 24 through a side heat spreader 36 to a ground pad 14 and the ground connection terminal 30. The ground pad 14 may be formed inside a circuit substrate 10, and the ground connection terminal 30 may be formed on a second surface (e.g., a lower surface) of the circuit substrate 10.

Heat discharged to the ground pad 14 and the ground connection terminal 30 may be further discharged through the module circuit substrate 100. The first semiconductor package 1P may further discharge heat generated by the semiconductor chip 24 through a surface heat spreader 40 to the outside.

The second semiconductor package 13P may be the same as the first semiconductor package 1P except that a third surface heat spreader 132 does not include a sidewall heat spreader. The second semiconductor package 13P may include a second semiconductor chip 24c and a second encapsulation layer 34a. The second semiconductor chip 24c may be formed on a second circuit substrate 10c and electrically connected to the second circuit substrate 10c through a second internal connection terminal 26b. The second encapsulation layer 34a may encapsulate the second semiconductor chip 24c (e.g., surround lateral side surfaces, an upper surface and a lower surface of the second semiconductor chip 24c). The third surface heat spreader 132 may be formed on an upper surface of the second encapsulation layer 34a. The third surface heat spreader 132 may include a metal material that facilitates heat dissipation.

Heat generated by the second semiconductor chip 24c may be discharged upward through the third surface heat spreader 132. The heat generated by the second semiconductor chip 24c may be discharged to the ground connection terminal 30a through a second ground pad 14a and a second internal interconnection 18a, which are formed in the second circuit substrate 10c.

The third semiconductor package 15P may be the same as the second semiconductor package 13P except that the third semiconductor package 15P does not include the third surface heat spreader 132. The third semiconductor package 15P may include a third semiconductor chip 24d and a third encapsulation layer 34b. The third semiconductor chip 24d may be located on a third circuit substrate 10d and is electrically connected to the third circuit substrate 10d through a third internal connection terminal 26c. The third encapsulation layer 34b may encapsulate the third semiconductor chip 24d (e.g., surround lateral side surfaces, an upper surface and a lower surface of the third semiconductor chip 24d).

Heat generated by the third semiconductor chip 24d may be discharged upward through the third encapsulation layer 34b. The heat generated by the third semiconductor chip 24d may be discharged to the ground connection terminal 30b through a third ground pad 14b and a third internal interconnection 18b, which are formed in the third circuit substrate 10d.

FIG. 9 is a cross-sectional view of a semiconductor package module 5PM according to an exemplary embodiment of the present inventive concepts.

The semiconductor package module SPM may be the same as the semiconductor package module 3PM of the exemplary embodiment of FIG. 8 except for a configuration of a fourth semiconductor package 7P. Accordingly, in the exemplary embodiment of FIG. 9, the same description as with reference to FIG. 8 will be omitted or briefly presented for convenience of explanation.

The semiconductor package module 5PM may include a plurality of semiconductor packages, for example, the fourth semiconductor package 7P and second and third semiconductor packages 13P and 15P, which are mounted on (e.g., disposed on) a module circuit substrate 100. Although FIG. 9 illustrates an example in which a plurality of semiconductor packages are arranged on only a first surface (e.g., an upper surface) of the module circuit substrate 100, in another exemplary embodiment, a plurality of semiconductor packages may be also arranged on a second surface of the module circuit substrate 100 (e.g., a lower surface), which is opposite to the first surface. In another exemplary embodiment, the plurality of semiconductor packages may be arranged only on the second surface of the module circuit substrate 100.

The fourth semiconductor package 7P and the second and third semiconductor packages 13P and ISP may be spaced apart from each other on the module circuit substrate 100 (e.g., in a direction parallel to an upper surface of the module circuit substrate 100). The fourth semiconductor package 7P and the second and third semiconductor packages 13P and 15P may be spaced apart from each other and individually dissipate heat on the module circuit substrate 100. For example, the fourth semiconductor package 7P and second and third semiconductor packages 13P and 15P may not collectively dissipate heat.

Accordingly, the fourth semiconductor package 7P and the second and third semiconductor packages 13P and 15P may not be affected by heat generated from each other. For example, in an exemplary embodiment in which the fourth semiconductor package 7P is a control semiconductor package configured to control the second semiconductor package 13P and the third semiconductor package 15P and generates a large amount of heat, the heat generated by the fourth semiconductor package 7P may not affect the second semiconductor package 13P and the third semiconductor package 15P.

Hereinafter, a connection relationship between the fourth semiconductor package 7P and the module circuit substrate 100 will be described. In the fourth semiconductor package 7P and the second and third semiconductor packages 13P and 15P, module ground pads 116, 124, and 128 may be connected to ground connection terminals 30, 30a, and 30b disposed on a lower surface of a circuit substrate 10, a second circuit substrate 10c and a third circuit substrate 10d of the fourth semiconductor package 7P, second semiconductor package 13P, and third semiconductor package ISP, respectively. In the fourth semiconductor package 7P and the second and third semiconductor packages 13P and ISP, module signal pads 122, 126, and 130 may be connected to signal connection terminals 28, 28a, and 28b disposed on a lower surface of a circuit substrate 10, a second circuit substrate 10c and a third circuit substrate 10d of the fourth semiconductor package 7P, second semiconductor package 13P, and third semiconductor package 15P, respectively.

The fourth semiconductor package 7P may dissipate heat through a heat spreader 42c as described above with reference to the exemplary embodiments of FIGS. 4A and 4B. The fourth semiconductor package 7P may discharge heat generated by a semiconductor chip 24 through a side heat spreader 36 to a ground pad 14 and the ground connection terminal 30. The ground pad 14 may be formed in the circuit substrate 10, and the ground connection terminal 30 may be formed on the second surface (e.g., a lower surface) of the circuit substrate 10.

The heat, which is discharged to the ground pad 14 and the ground connection terminal 30, may be further discharged through the module circuit substrate 100. The fourth semiconductor package 7P may further discharge the heat generated by the semiconductor chip 24 to the outside through a surface heat spreader 40c. Since a connection relationship between the second and third semiconductor packages 13P and 15P and the module circuit substrate 100 has been described with reference to FIG. 8, a description thereof will be omitted for convenience of explanation.

Although the semiconductor package modules 3PM and 5PM of the exemplary embodiments of FIGS. 8 and 9 have been described only using the above-described semiconductor packages 1P and 7P, the semiconductor packages 3P, 5P, 9P, and 11P may also be applied to the semiconductor package modules 3PM and 5PM shown in the exemplary embodiments of FIGS. 8 and 9.

FIG. 10 is a cross-sectional view of a semiconductor package module CPM according to a comparative example to be compared with the semiconductor package modules 3PM and SPM of FIGS. 8 and 9.

The semiconductor package module CPM according to the comparative example may include a plurality of comparative semiconductor packages, for example, first to third comparative semiconductor packages CP1, CP2, and CP3, which are mounted on a module circuit substrate 100. The module circuit substrate 200 may be a PCB. The first to third comparative semiconductor packages CP1, CP2, and CP3 may be spaced apart from each other on the module circuit substrate 200 (e.g., in a direction parallel to an upper surface of the module circuit substrate 200).

First to third module connection terminals 202, 204, and 206 may be disposed on the module circuit substrate 200. The first to third comparative semiconductor packages CP1, CP2, and CP3 may be mounted on the first to third module connection terminals 202, 204, and 206, respectively.

The first comparative semiconductor package CP1 may include a first semiconductor chip 214 and a first encapsulation layer 216, which are disposed on a first circuit substrate 208. The first semiconductor chip 214 may be connected to the first circuit substrate 208 through a first internal connection terminal 212, and the first encapsulation layer 216 may encapsulate the first semiconductor chip 214. The second comparative semiconductor package CP2 may include a second semiconductor chip 214a and a second encapsulation layer 216a, which are disposed on a second circuit substrate 208a. The second semiconductor chip 214a may be connected to the second circuit substrate 208a through a second internal connection terminal 212a, and a second encapsulation layer 216a may encapsulate the second semiconductor chip 214a. The third comparative semiconductor package CP3 may include a third semiconductor chip 214b and a third encapsulation layer 216b, which are disposed on a third circuit substrate 208b. The third semiconductor chip 214b may be connected to the third circuit substrate 208b through a third internal connection terminal 212b, and the third encapsulation layer 216b may encapsulate the third semiconductor chip 214b.

The first to third comparative semiconductor packages CP1, CP2, and CP3 may be connected to a comparative heat spreader 224 through heat transfer members 218, 218a, and 218b, which are located on upper surfaces of the first to third encapsulation layers 216, 216a, and 216b, respectively. The heat transfer member 218, 218a, and 218b may include a metal material that facilitates heat transfer. The comparative heat spreader 224 may include a sidewall heat spreader 220, which is located on at least one lateral side of the first and third comparative semiconductor packages CP1 and CP3, and an upper heat spreader 222 located on upper surfaces of the heat transfer members 218, 218a, and 218b.

The first to third comparative semiconductor packages CP1, CP2, and CP3 may collectively dissipate heat through the comparative heat spreader 224. Therefore, the first to third comparative semiconductor packages CP1, CP2, and CP3 may be affected by heat generated from each other unlike in exemplary embodiments of the present inventive concepts. For example, when the first comparative semiconductor package CP1 is a control semiconductor package configured to control the second comparative semiconductor package CP2 and the third comparative semiconductor package CP3 and generates a large amount of heat, the heat generated by the first comparative semiconductor package CP1 may affect the second comparative semiconductor package CP2 and the third comparative semiconductor package CP3.

FIG. 11 is a cross-sectional view of a semiconductor package module system PMS according to an exemplary embodiment of the present inventive concepts.

In the semiconductor package module system PMS according to the exemplary embodiment shown in FIG. 11, a plurality of module connectors, for example, first and second module connectors 342a and 342b may be adhered onto a motherboard substrate 300 (or a motherboard or a mainboard). First and second semiconductor package modules PMa and PMb may be inserted into the first and second module connectors 342a and 342b, respectively. A controller package 340 may control the first and second semiconductor package modules PMa and PMb. The controller package 340 may be disposed on the motherboard substrate 300 and may be spaced apart from the first module connectors 342a and 342b in a direction parallel to an upper surface of the motherboard substrate 300.

Each of the first and second semiconductor package modules PMa and PMb may include one of the semiconductor package module 1PM, 3PM, and SPM shown in the exemplary embodiments of FIGS. 7A, 7B, 8, and 9. For example, each of the first and second semiconductor package modules PMa and PMb may be the same as the semiconductor package module 1PM of FIGS. 7A and 7B, which is inserted into each of the first and second module connectors 342a and 342b.

The first semiconductor package module PMa may include encapsulation layers 304 and 306 and heat spreaders 317 and 318. The encapsulation layers 304 and 306 may be located on both first and second surfaces (e.g., upper and lower surfaces) of a module circuit substrate 100 and encapsulate semiconductor chips, respectively. The heat spreaders 317 and 318 may surround the encapsulation layers 304 and 306, respectively. The second semiconductor package module PMb may include encapsulation layers 308 and 310 and heat spreaders 319 and 320. The encapsulation layers 308 and 310 may be located on both the first and second surfaces of the module circuit substrate 100 and encapsulate semiconductor chips, respectively. The heat spreaders 319 and 320 may surround the encapsulation layers 308 and 310, respectively. The heat spreaders 317, 318, 319, and 320 may respectively surround the encapsulation layers 304, 306, 308, and 310 and individually dissipate heat generated by the semiconductor chips to the outside. The first and second semiconductor package modules PMa and PMb may individually include the heat spreaders 317, 318, 319, and 320 for the respective semiconductor chips and dissipate heat generated by the respective semiconductor chips. Therefore, in the semiconductor package module system PMS, the first and second semiconductor package modules PMa and PMb may be located a relatively large distance Ag1 (e.g., a distance in the direction of an upper surface of the motherboard substrate 300) apart from each other on the motherboard substrate 300 having a limited length or width. Therefore, the semiconductor package module system PMS may improve heat dissipation performance of the first and second semiconductor package modules PMa and PMb.

FIG. 12 is a cross-sectional view of a semiconductor package module system CPMS according to a comparative example to be compared with the semiconductor package module system PMS of FIG. 11.

The semiconductor package module system CPMS according to the comparative example may be the same as the semiconductor package module system PMS of FIG. 11 except for comparative heat spreaders 322 and 324. In the exemplary embodiment of FIG. 12, the same description as in FIG. 11 will be omitted or briefly presented. A plurality of module connectors, for example, first and second module connectors 342a and 342b, may be adhered onto a motherboard substrate 300. First and second comparative semiconductor package modules CPMa and CPMb may be inserted into the first and second module connectors 342a and 342b, respectively.

The first comparative semiconductor package module CPMa may include encapsulation layers 304 and 306 and the comparative heat spreader 322. The encapsulation layers 304 and 306 may be located on both surfaces of a module circuit substrate 100 and encapsulate semiconductor chips, respectively. The comparative heat spreader 322 may surround the encapsulation layers 304 and 306. The second semiconductor package module CPMb may include encapsulation layers 308 and 310 and the comparative heat spreader 324. The encapsulation layers 308 and 310 may be located on both surfaces of the module circuit substrate 100 and encapsulate semiconductor chips, respectively. The comparative heat spreader 324 may surround the encapsulation layers 308 and 310. The comparative heat spreaders 322 and 324 may surround all the encapsulation layers 304, 306, 308, and 310 and collectively dissipate heat generated by the semiconductor chips to the outside. The first and second comparative semiconductor package modules CPMa and CPMb may dissipate heat through the comparative heat spreaders 322 and 324, which are provided as an integrated type to surround all the semiconductor chips. Therefore, in the semiconductor package module system CPMS according to the comparative example, a distance Ag2 (e.g., a distance parallel to an upper surface of the motherboard substrate) between the first and second semiconductor package modules CPMa and CPMb on the motherboard substrate 300 having a limited length or width may be less than the distance Ag1 of FIG. 11. As a result, in the semiconductor package module system CPMS according to the comparative example, the heat dissipation performance of the first and second semiconductor package modules CPMa and CPMb may be degraded.

While exemplary embodiments of the present inventive concepts have been particularly shown and described with reference to embodiments thereof, it will be understood that various changes in form and details may be made therein without departing from the spirit and scope of the present inventive concepts.

What is claimed is:

1. A semiconductor package comprising:
a circuit substrate including a ground pad;
at least one semiconductor chip disposed on the circuit substrate and electrically connected to the circuit substrate;
an encapsulation layer encapsulating the at least one semiconductor chip; and
a heat spreader surrounding the encapsulation layer,
wherein the heat spreader comprises:
a side heat spreader disposed on a first surface of the circuit substrate and lateral side surfaces of the encapsulation layer, the side heat spreader is connected to the ground pad; and
a surface heat spreader disposed on an upper surface of the encapsulation layer.

2. The semiconductor package of claim 1, wherein the side heat spreader is integrally formed with the surface heat spreader.

3. The semiconductor package of claim 2, wherein a thickness of the surface heat spreader is greater than a thickness of the side heat spreader.

4. The semiconductor package of claim 2, wherein a thickness of the surface heat spreader is equal to a thickness of the side heat spreader.

5. The semiconductor package of claim 1, wherein:
the ground pad is connected to the side heat spreader on the first surface of the circuit substrate, and
the ground pad is connected to an external connection terminal formed on a second surface of the circuit substrate that is opposite the first surface, wherein an internal interconnection formed in the circuit substrate or an internal through interconnection passing through an entire thickness of the circuit substrate is configured to connect the ground pad to the external connection terminal.

6. The semiconductor package of claim 1, wherein the surface heat spreader comprises a pattern structure, wherein the pattern structure is disposed on the upper surface of the encapsulation layer and comprises a plurality of through grooves that are spaced apart from each other or a plurality of recess grooves that are spaced apart from each other.

7. The semiconductor package of claim 1, wherein the surface heat spreader comprises a first pattern structure including a plurality of first through grooves which expose the upper surface of the encapsulation layer and are spaced apart from each other.

8. The semiconductor package of claim 1, wherein:
the surface heat spreader comprises a base layer and a second pattern structure disposed on the base layer, the second pattern structure including a plurality of first recess grooves;
the base layer is disposed on the upper surface of the encapsulation layer; and
the plurality of first recess grooves expose an upper surface of the base layer, wherein the first recess grooves are spaced apart from each other.

9. The semiconductor package of claim 1, further comprising:
a third pattern structure disposed on the upper surface of the encapsulation layer and comprising a plurality of second recess grooves formed inward, the second recess grooves are spaced apart from each other,
wherein the surface heat spreader comprises a fourth pattern structure disposed on the third pattern structure, the fourth pattern structure comprising third recess grooves that overlap the second recess grooves.

10. The semiconductor package of claim 1, wherein:
the surface heat spreader comprises a first surface heat spreader and a second surface heat spreader disposed on the first surface heat spreader;
the first surface heat spreader is disposed on the upper surface of the encapsulation layer, the second surface heat spreader comprises a second base layer disposed on the first surface heat spreader and a fifth pattern structure disposed on the second base layer, the fifth pattern structure having a plurality of fourth recess grooves that are spaced apart from each other and expose an upper surface of the second base layer.

11. The semiconductor package of claim 1, wherein:
the circuit substrate further includes an external connection terminal disposed on a second surface of the circuit substrate that is opposite to the first surface, the external connection terminal is connected to the ground pad through an internal interconnection;
the semiconductor package further includes an additional circuit substrate having an additional ground pad, wherein the external connection terminal is further connected to the additional ground pad.

12. A semiconductor package comprising:
a circuit substrate comprising a ground pad disposed on a first surface of the circuit substrate;
an external connection terminal disposed on a second surface of the circuit substrate, the external connection terminal connected to the ground pad through an internal interconnection;
at least one semiconductor chip disposed on the first surface of the circuit substrate and electrically connected to the circuit substrate;
an encapsulation layer encapsulating the at least one semiconductor chip; and
a heat spreader surrounding the encapsulation layer,
wherein the heat spreader comprises:
a side heat spreader disposed on a top surface of the circuit substrate and lateral side surfaces of the encapsulation layer, the side heat spreader connected to the ground pad and configured to dissipate heat by conduction through the circuit substrate; and
a surface heat spreader disposed on an upper surface of the encapsulation layer and comprising a pattern structure having a plurality of through grooves that are spaced apart from each other or a plurality of recess grooves that are spaced apart from each other, the surface heat spreader is configured to dissipate heat by convection through the pattern structure.

13. The semiconductor package of claim 12, wherein:
the surface heat spreader comprises a first base layer disposed on the upper surface of the encapsulation layer; and
the pattern structure is disposed on the first base layer.

14. The semiconductor package of claim 12, further comprising an additional pattern structure having additional recess grooves formed in the encapsulation layer, wherein the surface heat spreader includes the plurality of recess grooves and the plurality of recess grooves overlap the additional recess grooves.

15. The semiconductor package of claim 12, wherein:
the surface heat spreader comprises a first surface heat spreader and a second surface heat spreader disposed on the first heat spreader;
the first surface heat spreader is disposed on the upper surface of the encapsulation layer, the second surface heat spreader comprises a second base layer disposed on the first surface heat spreader, and the pattern structure is disposed on the second base layer, the pattern structure including the plurality of recess grooves.

16. A semiconductor package module comprising:
a module circuit substrate having a module ground pad; and
a plurality of semiconductor packages connected to the module ground pad through an external connection terminal disposed on the module circuit substrate, the plurality of semiconductor packages is spaced apart from each other,
wherein at least one of the plurality of semiconductor packages comprises:
a circuit substrate including a ground pad connected to the external connection terminal through an internal interconnection;
at least one first semiconductor chip disposed on the circuit substrate and electrically connected to the circuit substrate;
an encapsulation layer encapsulating the at least one first semiconductor chip; and
a heat spreader surrounding the encapsulation layer,
wherein the heat spreader comprises:
a side heat spreader disposed on a top surface of the circuit substrate and lateral side surfaces of the encapsulation layer, the side heat spreader connected to the ground pad of the circuit substrate; and
a surface heat spreader disposed on an upper surface of the encapsulation layer.

17. The semiconductor package module of claim 16, wherein at least one of the plurality of semiconductor packages further comprises:
a second semiconductor chip disposed on a second circuit substrate;
a second encapsulation layer encapsulating the second semiconductor chip; and
a second surface heat spreader disposed on an upper surface of the second encapsulation layer.

18. The semiconductor package module of claim 16, wherein the plurality of semiconductor packages comprise a plurality of memory semiconductor packages, and at least one control semiconductor package that is configured to control the plurality of memory semiconductor packages.

19. The semiconductor package module of claim 18, wherein:
the at least one control semiconductor package is mounted on a central portion of the module circuit substrate; and
the plurality of memory semiconductor packages are mounted on both sides of the at least one control semiconductor package on the module circuit substrate.

20. The semiconductor package module of claim 16, wherein:
the surface heat spreader comprises a plurality of through grooves that are spaced apart from each other or a plurality of recess grooves that are spaced apart from each other, wherein the surface heat spreader is configured to dissipate heat generated by the at least one first semiconductor chip by convection; and
the side spreader is connected to the module ground pad through the external connection terminal, wherein the side spreader is configured to dissipate heat generated by the at least one first semiconductor chip by conduction through the module circuit substrate.
